(19) United States
(12) Patent Application Publication
(10) Pub. No.: US 2016/0320244 A1
(43) Pub. Date: Nov. 3, 2016

(54) ELECTRONIC DEVICE PROVIDED WITH ELECTRICAL ELEMENT AND TEMPERATURE DETECTOR

(71) Applicant: PANASONIC INTELLECTUAL PROPERTY MANAGEMENT CO., LTD., Osaka-shi (JP)

(72) Inventors: JUNICHI KIMURA, Osaka (JP); MASAHISA NAKAGUCHI, Osaka (JP); SHINICHI KOHDA, Kyoto (JP); NORIMITSU HOZUMI, Osaka (JP)

(21) Appl. No.: 15/108,756

(22) PCT Filed: Jan. 15, 2015
(86) PCT No.: PCT/JP2015/000146

§ 371 Date: Jun. 28, 2016

Related U.S. Application Data
(60) Provisional application No. 61/927,981, filed on Jan. 16, 2014.

(51) Int. Cl. G01K 1/14; G01K 1/16; H01L 23/367; G01K 7/22

(52) U.S. Cl. CPC G01K 1/14; G01K 7/22; G01K 1/16; H01L 23/367

(57) ABSTRACT

In an electronic device, A heat spreader is adhered to a surface of the substrate on a side opposite to the lower surface of the substrate (hereinafter referred to as “upper surface”) by an adhesive sheet. The heat spreader supports a power transistor cooperatively with the substrate. The power transistor which is an electrical element and the heat spreader are adhered to each other by an adhesive sheet on an adhering surface on a side opposite to an adhering surface where the heat spreader is adhered to the substrate. A bus bar and the power transistor are adhered to each other by an adhesive sheet on an adhering surface on a side opposite to an adhering surface where the power transistor is adhered to the heat spreader. The thermistor is connected to a lead which is a conductive line, and is disposed on an upper surface side of substrate.

### TECHNICAL FIELD

The present invention relates to an electronic device on which an electrical element, a power semiconductor element and a temperature detector such as a thermistor are mounted.

### BACKGROUND ART

In an electronic device on which a power semiconductor element is mounted, generation of heat by a power semiconductor element is detected by a temperature sensing element such as a diode or a temperature sensor such as a thermistor which is integrated into a control integrated circuit. When it is detected that the power semiconductor element is in an overheated state, driving of the power semiconductor element is readily stopped by the control integrated circuit.

In such an electronic device, it is necessary that heat generated by the switching element is efficiently transferred to the temperature sensing element or the temperature sensor so that a temperature is measured with high accuracy. For example, PTL 1 proposes the structure in which a power semiconductor element and a thermistor are mounted on a heat radiation plate.

### CITATION LIST

### Patent Literature

PTL 1: Unexamined Japanese Patent Publication No. 2009-525885

However, in a semiconductor device disclosed in PTL 1, as shown in FIG. 5, temperature sensor 7 is mounted on an upper surface of extending portion 15 of heat radiation plate 14 which supports IGBT (Insulated Gate Bipolar Transistor) chip 4 and free hole diode 5.

In the semiconductor device having such a configuration, a large amount of heat generated by IGBT chip 4 is radiated from a lower surface of heat radiation plate 14 through first frame portion 2a of lead frame 2 and heat radiation plate 14 within a short time Accordingly, temperature sensor 7 mounted on extending portion 15 of heat radiation plate 14 has a drawback that a detected temperature is largely different from a true temperature of IGBT chip 4.

### SUMMARY OF THE INVENTION

The present invention has been made to overcome the above drawback. According to the present invention, there is provided an electronic device including a base member which includes a heat radiation member; an electrical element adhered to the base member; and a temperature detector, wherein heat resistance between the base member and the temperature detector is larger than heat resistance between the base member and the electrical element.

According to the electronic device of the present invention, a temperature of the electrical element can be detected with high accuracy.

In a case where the electrical element is brought into an overheated state, driving of the electrical element can be stopped readily.

### BRIEF DESCRIPTION OF DRAWINGS

FIG. 1 is a perspective view of an electronic device according to a first exemplary embodiment.

FIG. 2 is a perspective view of the electronic device according to the first exemplary embodiment in a state where a sealing resin is not shown in the drawing.

FIG. 3 is a cross-sectional view of the electronic device according to the first exemplary embodiment in a state where the sealing resin is not shown in the drawing.

FIG. 4 is a schematic view of a cross section of an electronic device according to a second exemplary embodiment in a state where a sealing resin is not shown in the drawing.

FIG. 5 is a cross-sectional view showing a conventional semiconductor device.

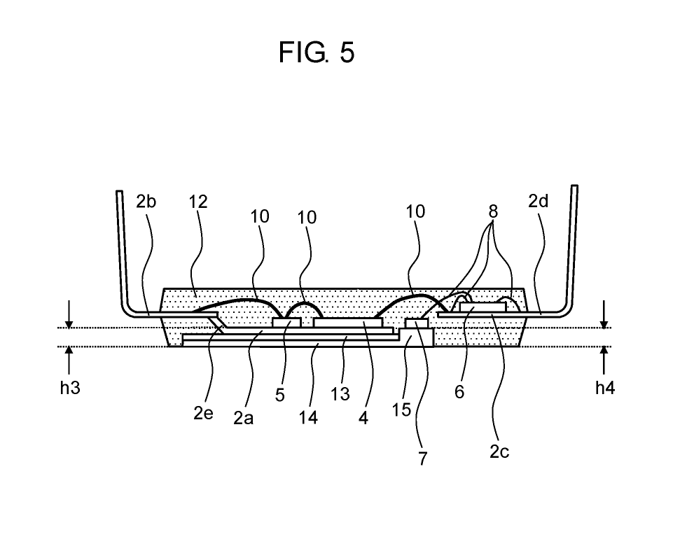

FIG. 6 is a circuit diagram of a thermal circuit according to the first exemplary embodiment.

### DESCRIPTION OF EMBODIMENTS

### First Exemplary Embodiment

A first exemplary embodiment of the present invention is described with reference to the drawings.

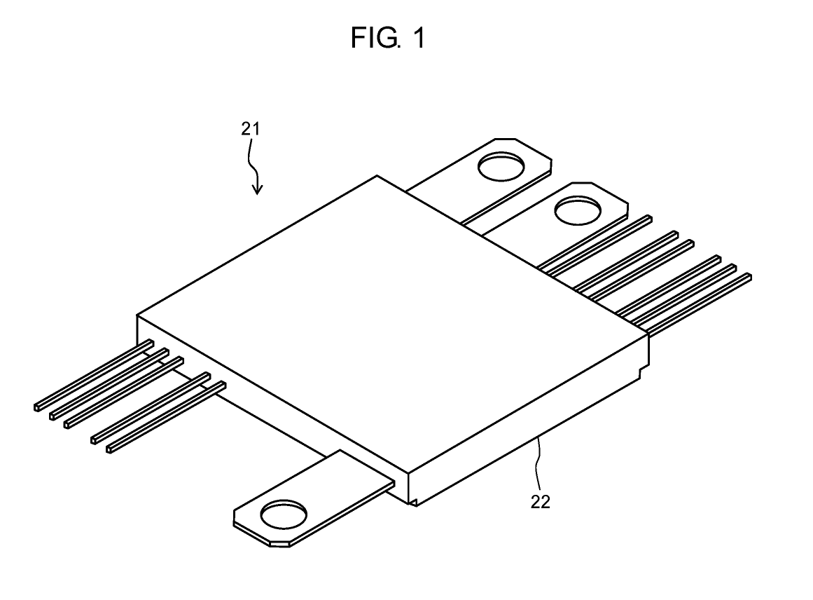

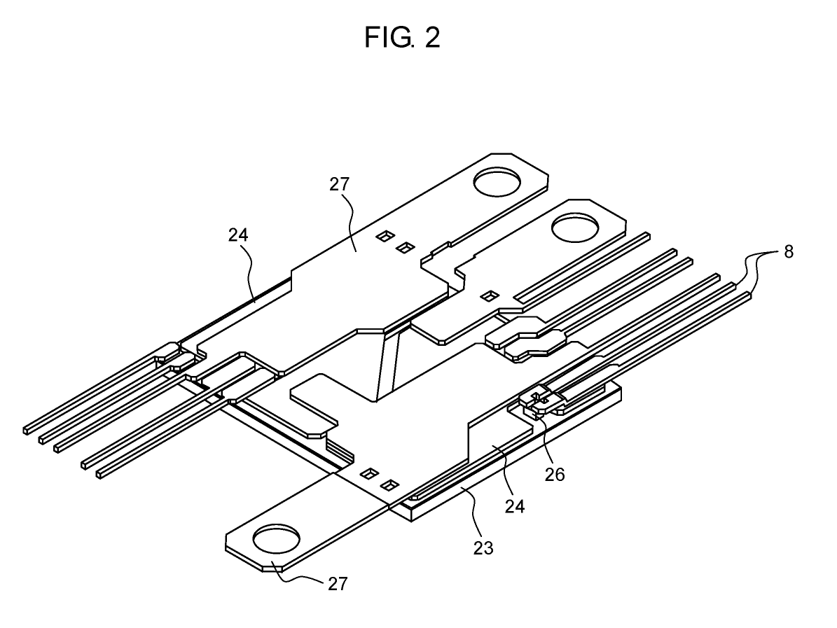

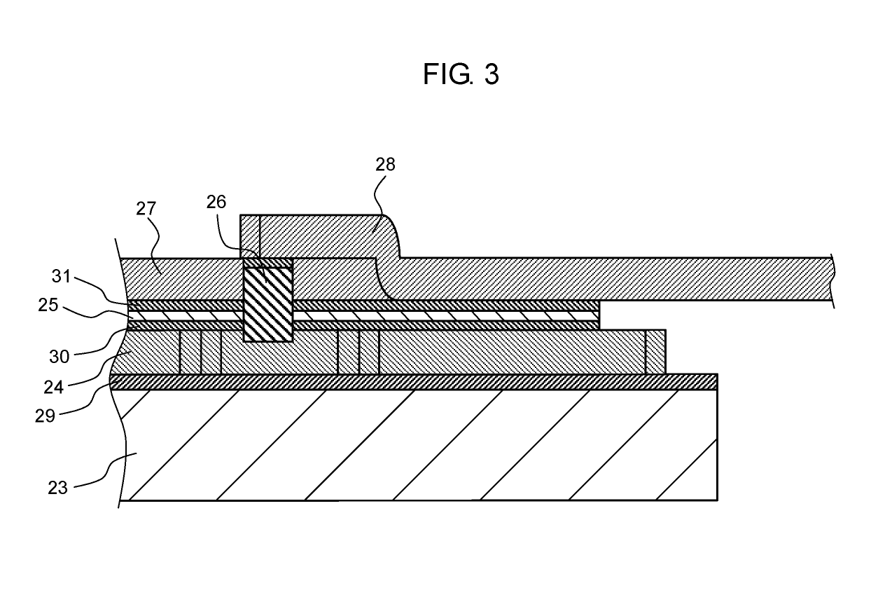

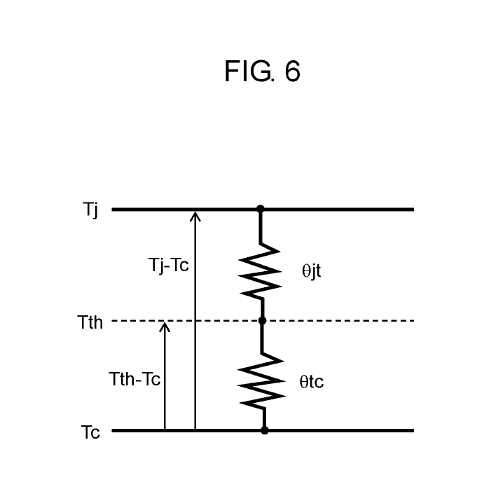

FIG. 1 is a perspective view of an electronic device according to a first exemplary embodiment. FIG. 2 is a perspective view of the electronic device according to the first exemplary embodiment in a state where a sealing resin is not shown in the drawing. FIG. 3 is a cross-sectional view of the electronic device according to the first exemplary embodiment in a state where the sealing resin is not shown in the drawing. FIG. 6 is a circuit diagram of a thermal circuit according to the first exemplary embodiment.

Electronic device 21 includes power transistor 25, thermistor 26 and the like, and power transistor 25, thermistor 26 and the like are protected by sealing resin 22.

Numeral 23 indicates a substrate, numeral 24 indicates a heat spreader, numeral 27 indicates a bus bar, numeral 28 indicates a lead of a thermistor, and numerals 29, 30, 31 indicate adhesive sheets respectively.

In electronic device 21, one surface (hereinafter referred to as “lower surface”) of substrate 23 is not covered by a sealing resin 22 and is exposed to the outside. Heat spreader 24 which is a heat radiation member is adhered to a surface of substrate 23 on a side opposite to the lower surface of substrate 23 (hereinafter referred to as “upper surface”) by adhesive sheet 29 which is an adhesive member. Heat spreader 24 supports power transistor 25 cooperatively with substrate 23 as base members. Power transistor 25 which is an electrical element and heat spreader 24 are adhered to each other by adhesive sheet 30 on an adhering surface on a side opposite to an adhering surface where heat spreader 24 is adhered to substrate 23. Bus bar 27 which is a power source plate and power transistor 25 are adhered to each other by adhesive sheet 31 on an adhering surface on a side opposite to an adhering surface where power transistor 25 is adhered to heat spreader 24. Thermistor 26 which is a temperature detector is connected to lead 28 which is a conductive line, and is disposed on an upper surface side of substrate 23. A cut-away portion having a size larger than a size of thermistor 26 is formed in heat spreader 24 in a region disposed adjacently to power transistor 25 which is positioned on the upper surface side of substrate 23, and thermistor 26 is disposed in the cut-away portion. That is, as one mode of the electronic device, the heat radiation member may be cut away at a portion where the temperature detector and the substrate overlap with each other as viewed from above the electronic device.

To prevent thermistor 26 and substrate 23 from being adhered to each other, lead 28 which is the conductive line for thermistor 26 is bent toward an upper side of the electronic device in an S shape as viewed from a lateral side in the vicinity of a portion where thermistor 26 and the conductive line are adhered to each other. Further, sealing resin 22 is filled in between the members while exposing a part of the lead, so that electronic device 21 is covered by sealing resin 22.

In the electronic device having the above configuration, heat generated by power transistor 25 is transferred to heat spreader 24 through adhesive sheet 30, is further transferred to substrate 23 through adhesive sheet 29, and is radiated from the lower surface of the substrate. Power transistor 25 can be cooled in this manner.

Heat generated by power transistor 25 is transferred to sealing resin 22 which also functions as a heat conductor between power transistor 25 and thermistor 26, and thermistor 26 detects a temperature of power transistor 25 transferred to sealing resin 22.

It is desirable that temperature Tj of power transistor 25 and temperature Tth of thermistor 26 have a proportional relationship. When heat resistance between substrate 23 and thermistor 26 is larger than heat resistance between substrate and power transistor 25, the heat resistance between substrate 23 and thermistor 26 is less likely to be influenced by a change in temperature Tc of substrate 23. Moreover, when heat resistance between power transistor 25 and thermistor 26 is smaller than the heat resistance between substrate 23 and thermistor 26, the heat resistance between power transistor 25 and thermistor 26 is further less likely to be influenced by a change in temperature Tc of substrate 23.

To detect a temperature of power transistor 25 with high accuracy, it is desirable that thermistor 26 is disposed as close as possible to power transistor 25.

By making a distance between power transistor 25 and thermistor 26 smaller than a distance between substrate 23 and thermistor 26, heat resistance between power transistor 25 and thermistor 26 becomes smaller than heat resistance between substrate 23 and thermistor 26. As a matter of course, power transistor 25 and substrate 23 are in contact with each other by way of adhesive sheet 31 for radiation of heat and hence, heat resistance between power transistor 25 and substrate 23 is smaller than heat resistance between power transistor 25 and thermistor 26 as well as heat resistance between substrate 23 and thermistor 26.

Further, the heat of thermistor 26 is hardly transferred to substrate 23, while the heat of power transistor 25 is easily transferred to thermistor 26.

With such a configuration, a temperature of thermistor 26 is not easily lowered and hence, a temperature of power transistor 25 can be detected with high accuracy.

A thermal circuit of electronic device 21 adopting the above configuration is shown in FIG. 6. Assuming that a temperature of power transistor 25 is Tj, a temperature of thermistor 26 is Tth, a temperature of substrate 23 is Tc, heat resistance between power transistor 25 and thermistor 26 is θjt, and heat resistance between thermistor 26 and substrate 23 is θtc, a relationship between respective parameters is expressed by the following formula.

(Tth−Tc)=θtb×(Tj−Tc)/(θtc+θjt)

From this formula, temperature Tj is obtained by the following formula.

Tj=((θtc+θjt)Tth−θjt·Tc)/θtc

In the formula, heat resistance θtc and heat resistance θjt are values determined depending on the structure of electronic device 21 and are known values. Accordingly, temperature Tj can be calculated by measuring temperature Tth and temperature Tb.

By disposing power transistor 25, thermistor 26 and substrate 23 such that θtc>>θjt is satisfied, it is possible to make Tj and Tth substantially equal to each other (Tj≅Tth). Accordingly, temperature Tj of power transistor 25 can be accurately measured by measuring temperature Tth of thermistor 26.

Assuming that thermal conductivity is λ, an effective area is A, and a distance is 1, heat resistance θ is expressed by θ=1/(λ×A). Accordingly, in order to dispose power transistor 25, thermistor 26 and substrate 23 such that θtc>>θjt is satisfied, it is sufficient that a distance between power transistor 25 and thermistor 26 is set smaller than a distance between thermistor 26 and substrate 23.

Further, by disposing thermistor 26 and power transistor 25 such that thermistor 26 and power transistor 25 are in contact with each other, θjt becomes substantially 0 (θjt≅0) and hence, Tj and Tth become substantially equal to each other (Tj≅Tth). On the other hand, in the conventional art, temperature sensor 7 is in contact with heat radiation plate 14 so that, θtc becomes substantially 0 (θtc≅0) and hence, temperature Tj cannot be calculated from temperature Tth and temperature Tc.

### Second Exemplary Embodiment

A second exemplary embodiment according to the present invention is described with reference to the drawings.

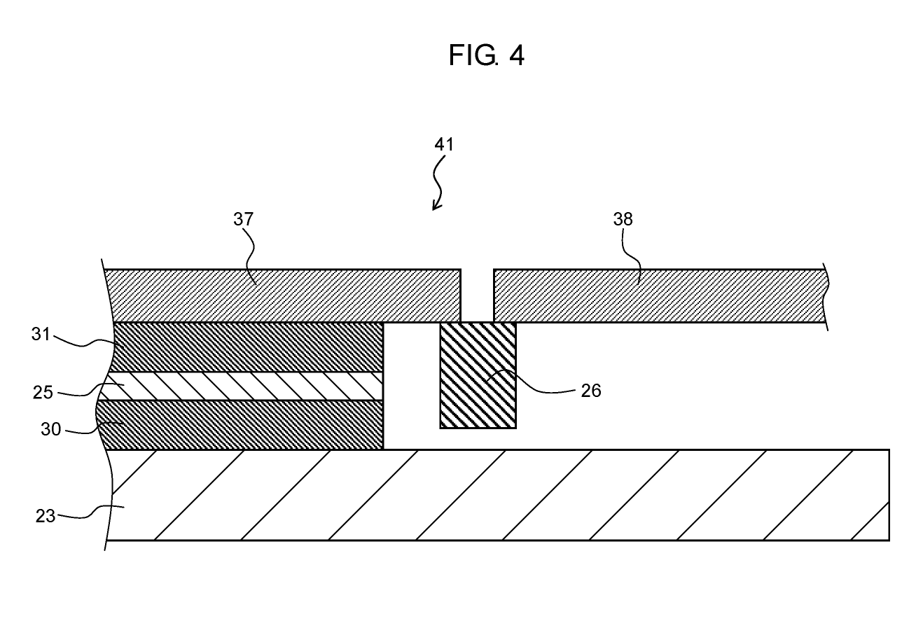

FIG. 4 is a schematic view of a cross section of an electronic device according to a second exemplary embodiment in a state where a sealing resin is not shown in the drawing. The description of parts identical to the parts of the first exemplary embodiment is omitted. Power transistor 25, thermistor 26 and the like are sealed by a sealing resin (not shown in the drawing). What makes electronic device 41 largely differ from electronic device 21 lies in bus bar 37 and lead 38 of a thermistor. Bus bar 37 is connected to a fixed electrode for power transistor 25 such as a power source or a ground which is provided for fixing a voltage. The voltage of the bus bar 37 is constant and hence, one electrode of thermistor 26 can be connected to bus bar 37. The other electrode of thermistor 26 is connected to lead 38. Heat which the thermistor receives is converted into an electrical signal, and the electrical signal is transmitted through lead 38.

As in the case of the first exemplary embodiment, lead 38 may be bent upward in an S shape as viewed from a lateral side. Alternatively, lead 38 may be formed into other shapes provided that substrate 23 and thermistor 26 are not in contact with each other.

The electronic device has the above-mentioned configuration and hence, heat generated by power transistor 25 is transferred to bus bar 37 through adhesive sheet 31. Thermistor 26 detects a temperature of power transistor 25 by receiving not only heat transferred to sealing resin 22 from power transistor 25 but also heat transferred to bus bar 37 from power transistor 25.

Heat resistance of bus bar 37 is smaller than heat resistance of sealing resin 22 and hence, compared to the configuration in the first exemplary embodiment of the present invention, heat generated by power transistor 25 is easily transferred to thermistor 26 through bus bar 37. Accordingly, a temperature of power transistor 25 can be readily detected by thermistor 26 with high accuracy.

With such a configuration, when a switching element is brought into an overheated state, driving of the switching element can be stopped readily.

The other electrode of thermistor 26 may be connected to a signal line for power transistor 25 in place of bus bar 37.

Thermistor 26 may be in contact with an upper surface or a side surface of power transistor 25. In such a case, heat generated by power transistor 25 is directly transferred to thermistor 26. When thermistor 26 is in contact with the upper surface of power transistor 25, a contact area is increased compared to a case where thermistor 26 is in contact with the side surface of power transistor 25 and hence, heat resistance is lowered. On the other hand, when thermistor 26 is in contact with the side surface of power transistor 25, a thickness of the electronic device can be reduced.

### INDUSTRIAL APPLICABILITY

The electronic device of the present invention can be effectively applicable as an electronic device, a semiconductor device or the like on which an electronic element, a power semiconductor element and the like, and a temperature detector such as a thermistor are mounted.

### REFERENCE MARKS IN THE DRAWINGS

21, 41: electronic device

22: sealing resin

23: substrate

24: heat spreader

25: power transistor

26: thermistor

27, 37: bus bar

28, 38: lead

29, 30, 31: adhesive sheet

1. An electronic device comprising:
a base member which includes a heat radiation member:
an electrical element adhered to the base member; and
a temperature detector,
wherein heat resistance between the base member and the temperature detector is larger than heat resistance between the base member and the electrical element.

2. The electronic device according to claim 1, wherein
heat resistance between the electrical element and the temperature detector is smaller than the heat resistance between the base member and the temperature detector.

3. The electronic device according to claim 2, wherein
a sealing resin is filled in between the electrical element and the temperature detector.

4. The electronic device according to claim 3, wherein
heat resistance of an adhesive agent which adheres the electrical element and the heat radiation member to each other is smaller than heat resistance of the sealing resin.

5. The electronic device according to claim 1, wherein
a distance between the electrical element and the temperature detector is shorter than a distance between the base member and the temperature detector.

6. The electronic device according to claim 1, further comprising a conductive line which is connected to a fixed electrode for the electrical element, wherein
the temperature detector is connected to the conductive line which is connected to the fixed electrode for the electrical element.

7. The electronic device according to claim 1, further comprising the conductive line which is connected to the signal electrode of the electrical element, wherein
the temperature detector is connected to the conductive line connected to the signal electrode of the electrical element.

8. The electronic device according to claim 5, wherein
a conductive line adhered to the temperature detector is bent toward away from the substrate in a vicinity of a portion where the temperature detector and the conductive line are adhered to each other.

9. The electronic device according to claim 1, wherein
the heat radiation member is cut away at a portion where the temperature detector and the substrate overlap with each other as viewed from above the electronic device.
